(19) United States
(12) Patent Application Publication
(10) Pub. No.: US 2026/0032981 A1
(43) Pub. Date: Jan. 29, 2026

(54) SELF-ALIGN MULTI TRENCH MOSFET AND MANUFACTURING METHOD OF THE SAME

(71) Applicant: Hon Hai Precision Industry Co., Ltd., New Taipei City (TW)

(72) Inventors: Yi-Kai HSIAO, New Taipei City (TW); Chia-Lung HUNG, New Taipei City (TW); Wei-Cheng YU, New Taipei City (TW); Hao-Chung KUO, New Taipei City (TW)

(73) Assignee: Hon Hai Precision Industry Co., Ltd., New Taipei City (TW)

(21) Appl. No.: 18/919,400

(22) Filed: Oct. 17, 2024

(30) Foreign Application Priority Data
Jul. 23, 2024 (TW) 113127394

(51) Int. Cl. H01L 29/423; H01L 29/66; H01L 29/78

(52) U.S. Cl. CPC H10D 64/513; H10D 30/025; H10D 30/63; H10D 64/514

(57) ABSTRACT

A manufacturing method of a self-align multi trench MOSFET includes forming an epitaxial layer on a substrate, forming a deep well region in the epitaxial layer, and forming a first conductive type heavily doped region in the deep well region on the surface of the epitaxial layer. A patterned hard mask is formed on the surface of the epitaxial layer to expose a portion of the epitaxial layer. A multiple trench formation process is performed to form trenches with stepped sidewalls in the epitaxial layer. Each process within the multiple trench formation process includes etching the exposed epitaxial layer and trimming the patterned hard mask to expose the surface of the epitaxial layer. After the multiple trench formation process, the patterned hard mask is removed. A gate dielectric layer is formed above the bottoms and stepped sidewalls of the trenches, and a gate is formed in the trenches.

### CROSS-REFERENCE TO RELATED APPLICATION

This application claims the priority benefit of Taiwan application serial no. 113127394, filed on Jul. 23, 2024. The entirety of the above-mentioned patent application is hereby incorporated by reference herein and made a part of this specification.

### BACKGROUND

### Technical Field

The disclosure relates to a trench MOSFET, and in particular relates to a self-align multi trench MOSFET and a manufacturing method of the same.

### Description of Related Art

In the field of silicon carbide power devices, reducing on-resistance to increase power density is a direction of development that both industry and academia are striving to advance. Therefore, compared with existing planar MOSFETs, trench MOSFETs with lower on-resistance have become the focus of research and development of power devices.

However, the excessively high electric field at the bottom of the gate in a trench-structured MOSFET results in reliability that fails to meet requirements.

### SUMMARY

A manufacturing method of a self-align multi trench MOSFET, which can manufacture a trench MOSFET with low on-resistance and reduced electric field at the bottom of the gate in a self-aligned manner, is provided in the disclosure.

A self-align multi trench MOSFET, which can reduce on-resistance and improve device reliability, is provided in the disclosure.

The manufacturing method of a self-align multi trench MOSFET of the disclosure includes the following operation. An epitaxial layer is formed on the substrate, and the epitaxial layer has a first conductive type. A deep well region is formed in the epitaxial layer, and the deep well region has a second conductive type. A first conductive type heavily doped region is formed in the deep well region of a surface of the epitaxial layer. A patterned hard mask is formed on the surface of the epitaxial layer to expose a portion of the epitaxial layer. A multiple trench formation process is performed to form multiple trenches with a stepped sidewall in the epitaxial layer. Each process within the multiple trench formation process includes etching the exposed epitaxial layer and trimming the patterned hard mask to expose the surface of the epitaxial layer. Then, the patterned hard mask is removed. A gate dielectric layer is formed above a bottom and the stepped sidewall of the trenches. A gate is formed in the trenches.

Another manufacturing method of a self-align multi trench MOSFET of the disclosure includes the following operation. An epitaxial layer is formed on the substrate, and the epitaxial layer has a first conductive type. A deep well region is formed in the epitaxial layer, and the deep well region has a second conductive type. A first conductive type heavily doped region is formed in the deep well region of a surface of the epitaxial layer. A patterned hard mask is formed on the surface of the epitaxial layer to expose a portion of the epitaxial layer. A first etching is performed to the exposed epitaxial layer to form multiple trenches. A material layer is formed in the trenches, and the material layer has etching selectivity relative to the epitaxial layer. The patterned hard mask is trimmed to expose a portion of a surface of the epitaxial layer. A second etching is performed on the exposed epitaxial layer to expand the trenches and form a stepped sidewall therein. Then, the patterned hard mask and the material layer are removed. A gate dielectric layer is formed above a bottom and the stepped sidewall of the trenches. A gate is formed in the trenches.

A self-align multi trench MOSFET of the disclosure includes a substrate, an epitaxial layer, a deep well region, a first conductive type heavily doped region, multiple trenches, a barrier layer, a gate dielectric layer, and a gate. The epitaxial layer is disposed on the substrate, and the epitaxial layer has a first conductive type. The deep well region is formed in the epitaxial layer, and the deep well region has a second conductive type. The first conductive type heavily doped region is formed in the deep well region of a surface of the epitaxial layer. Multiple trenches extend inwardly from the surface of the epitaxial layer, and the trenches have a stepped sidewall. The barrier layer is located at a bottom of the trenches. The gate dielectric layer is disposed on the stepped sidewall of the trenches and the barrier layer. The gate is disposed in the trenches.

Based on the above, the disclosure employs a self-aligned method to manufacture a multi trench structure. This approach not only increases the thickness of the oxide layer or dielectric layer at the bottom of the gate to reduce the electric field, but also provides greater conduction current and further reduces on-resistance by reducing the spacing between the trenches from both sides and expanding the width of the gate in the trench.

In order to make the aforementioned features of the disclosure comprehensible, embodiments accompanied with drawings are described in detail below.

### BRIEF DESCRIPTION OF THE DRAWINGS

FIG. 1A to FIG. 1J are cross-sectional schematic diagrams of the manufacturing process of a self-align multi trench MOSFET according to the first embodiment of the disclosure.

FIG. 2A to FIG. 2B are cross-sectional schematic diagrams of the manufacturing process of a self-align multi trench MOSFET according to the second embodiment of the disclosure.

FIG. 3A to FIG. 3C are cross-sectional schematic diagrams of the manufacturing process of a self-align multi trench MOSFET according to the third embodiment of the disclosure.

FIG. 4 is a cross-sectional schematic diagram of an intermediate stage of the manufacturing process of a self-align multi trench MOSFET according to the fourth embodiment of the disclosure.

FIG. 5 is a cross-sectional schematic diagram of a self-align multi trench MOSFET according to the fifth embodiment of the disclosure.

FIG. 6A is a top view of an example of the self-align multi trench MOSFET of FIG. 5.

FIG. 6B is a top view of another example of the self-align multi trench MOSFET of FIG. 5.

### DETAILED DESCRIPTION OF DISCLOSED EMBODIMENTS

The following examples are described in detail with the accompanying drawings, but the provided examples are not intended to limit the scope of the disclosure. In addition, for convenience of illustration, the dimensions of regions or film layers in the drawings are not actual proportions.

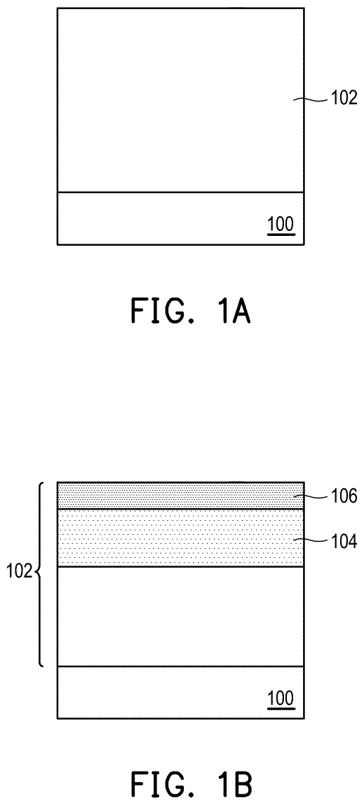

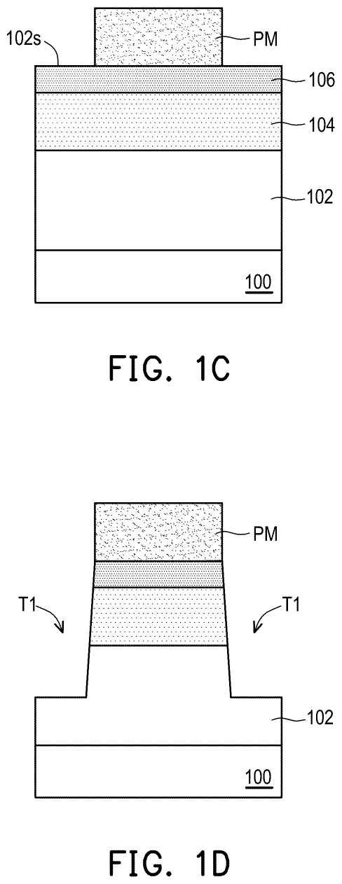

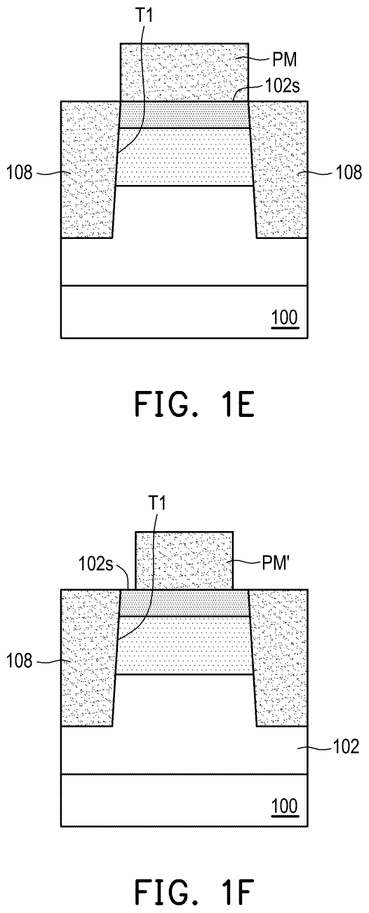

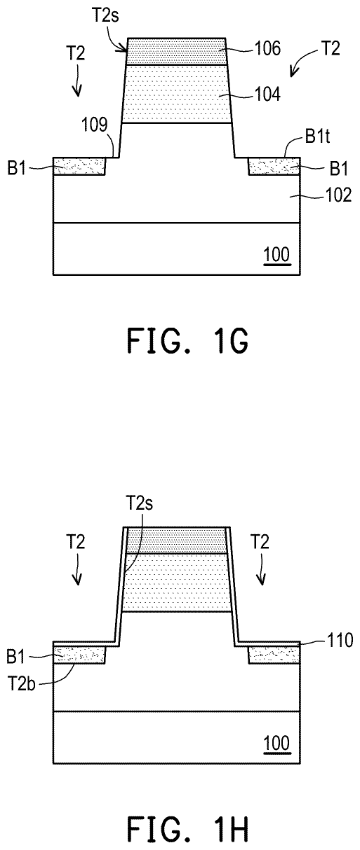

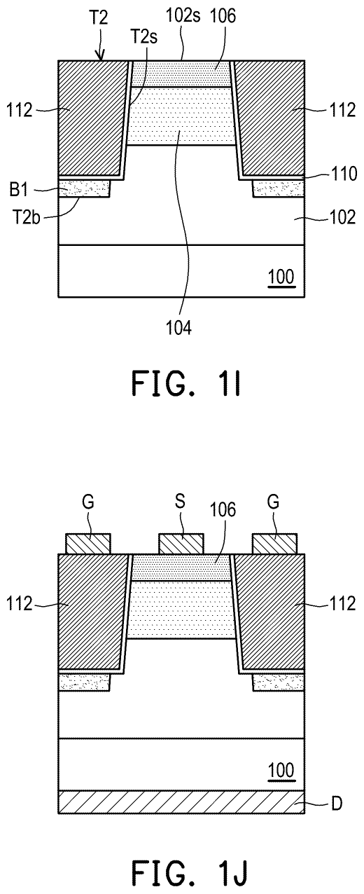

FIG. 1A to FIG. 1J are cross-sectional schematic diagrams of the manufacturing process of a self-align multi trench MOSFET according to the first embodiment of the disclosure.

Referring to FIG. 1A, an epitaxial layer 102 is formed on a substrate 100, in which the substrate 100 is, for example, a silicon carbide substrate, and the epitaxial layer 102 is, for example, an epitaxial layer of a first conductive type.

Then, referring to FIG. 1B, a deep well region 104 and a first conductive type heavily doped region 106 are formed in the epitaxial layer 102, in which the deep well region 104 has a second conductive type. In one embodiment, the first conductive type is N type and the second conductive type is P type; in another embodiment, the first conductive type is P type and the second conductive type is N type. The method of forming the deep well region 104 and the first conductive type heavily doped region 106 is, for example, an ion implantation process, and the ion implantation process can be a general multi-channel ion implantation process, but the disclosure is not limited thereto.

Next, referring to FIG. 1C, a patterned hard mask PM is formed on the surface 102s of the epitaxial layer 102 to expose a portion of the surface 102s of the epitaxial layer 102. The method of forming the patterned hard mask PM is, for example, but not limited to, the following steps. First, a layer of photoresist is uniformly applied to the surface 102s of the epitaxial layer 102. Subsequently, the photoresist is patterned by using a photomask process to obtain a patterned hard mask PM that covers a portion of the surface 102s of the epitaxial layer 102.

Afterwards, in order to form multiple trenches with stepped sidewalls in the epitaxial layer 102, please refer to FIG. 1D. A first etching process is performed on the exposed epitaxial layer 102 by using the patterned hard mask PM as an etching mask to form an initial trench T1.

Subsequently, referring to FIG. 1E, a material layer 108 is formed in the initial trench T1. The material layer 108 has etching selectivity relative to the epitaxial layer 102, so during subsequent etching of the epitaxial layer 102, the material layer 108 can protect the epitaxial layer 102 below the material layer 108. However, the disclosure is not limited thereto. In some embodiments, the step of FIG. 1E can be omitted, the next step can be performed directly, and the final trench profile can be obtained by controlling the size of the initial trench T1. For example, the initial trench T1 may be half the size (depth) of the final trench, and so on.

Next, referring to FIG. 1G, the patterned hard mask PM (of FIG. 1E) is trimmed to obtain a smaller patterned hard mask PM′ and expose a portion of the surface 102s of the epitaxial layer 102. The method for trimming the patterned hard mask PM is, for example, but not limited to, wet etching or other suitable processes, and this step does not require an additional photomask process.

Next, referring to FIG. 1G, a second etching process is performed on the exposed epitaxial layer 102 by using the patterned hard mask PM′ (of FIG. 1F) as an etching mask to expand the trench T1 (of FIG. 1F) and form a trench T2 with stepped sidewalls T2s in the epitaxial layer 102. Then, the patterned hard mask PM′ and the material layer 108 are removed. The removal order of the patterned hard mask PM′ and the material layer 108 can be interchanged, or a method capable of simultaneously removing both the patterned hard mask PM′ and the material layer 108 may be used to remove these two layers simultaneously. Next, a barrier layer B1 may be formed at the bottom of the trench T2. The material of the barrier layer B1 is, for example, silicon oxide (SiO₂), silicon nitride (SiN), or a high-k material. In one embodiment, a method of forming the barrier layer B1 includes first performing a deposition process (fill-in) followed by an etch-back process, and the aforementioned deposition process is, for example, CVD or ALD. In another embodiment, the method of forming the barrier layer B1 includes first performing an ion implantation process followed by an oxidation process. The dopants used in the aforementioned ion implantation process are not limited to P type, N type, or inert gases (such as Ar), which are intended to achieve a faster oxidation rate. The top surface B1t of the barrier layer B1 in the figure is coplanar with the top 109 of the lowest step of the stepped sidewall T2s, but not limited thereto. In some embodiments, if the stepped sidewall has more than three steps, the top surface of the barrier layer B1 may be coplanar with the top of the penultimate step of the stepped sidewall, and so on.

In this embodiment, the trench T2 with stepped sidewalls T2s is formed through two etching processes, so there is only one step in the stepped sidewalls T2s, but the disclosure is not limited thereto. In other embodiments, the processes of FIG. 1F and FIG. 1G can be repeated at least once to form a trench with stepped sidewalls having more steps.

Then, referring to FIG. 1H, a gate dielectric layer 110 is formed above the bottom T2b of the trench T2 and on the stepped sidewalls T2s. The method of forming the gate dielectric layer 110 is, for example, a deposition process such as ALD or CVD. Alternatively, a deposition process (fill-in) followed by an etch-back process may be performed to form a high-quality gate dielectric layer 110, such as a gate dielectric layer 110 with a uniform thickness, to improve reliability. The material of the gate dielectric layer 110 is, for example, SiO₂, SiN, or a high-k material.

Next, referring to FIG. 1I, gates 112 are formed in multiple trenches T2. The method of forming the gate 112 is, for example, but not limited to, the following steps. A conductive material (not shown) is first deposited or filled on the epitaxial layer 102, and then an etch-back process or a chemical mechanical planarization (CMP) process is used to remove the conductive material outside the trench T2 and expose the surface 102s of the epitaxial layer 102. In this embodiment, the barrier layer B1 at the bottom of the trench T2 can increase the protection under the gate 112 and improve the reliability, thereby achieving the effect of optimizing the device.

Subsequently, referring to FIG. 1J, a back-end-of-line process (BEOL) can be performed to form the gate electrode G on the gate 112, the source electrode S on the first conductive type heavily doped region 106, and the drain electrode D on the back of the substrate 100. The gate electrode G, the drain electrode D, and the source electrode S may be metal, and may be formed simultaneously or separately using the same process.

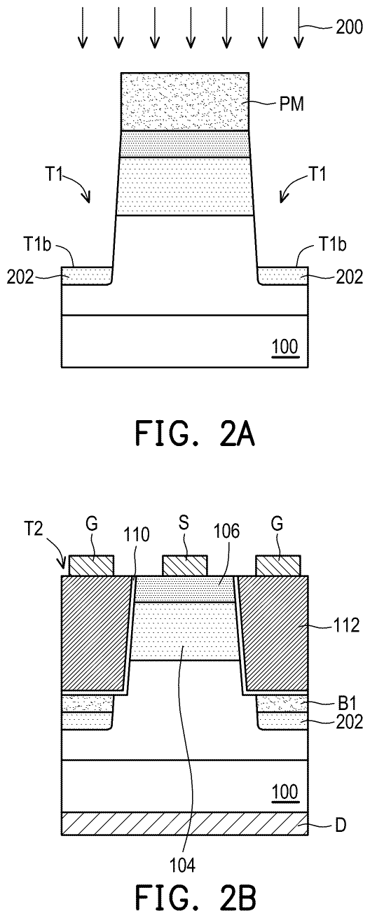

FIG. 2A to FIG. 2B are cross-sectional schematic diagrams of the manufacturing process of a self-align multi trench MOSFET according to the second embodiment of the disclosure. The manufacturing method starts after the steps relative to FIG. 1D, in which a forming step of a second conductive type heavily doped region is added. Moreover, in FIG. 2A to FIG. 2B, the same reference numerals as those in the first embodiment are used to represent the same or similar parts and components. The relevant content of the same or similar parts and components may be referenced from the contents of the first embodiment, and are not repeated herein.

Referring to FIG. 2A, after forming the initial trench T1, a second conductive type heavily doped region 202 may be formed below the bottom T1b of the initial trench T1. The method of forming the second conductive type heavily doped region 202 is, for example, the second conductive type ion implantation 200. No additional photomask process is required, as the patterned hard mask PM can be utilized as a mask.

Afterwards, the process of FIG. 1E to FIG. 1J can be followed to obtain the self-align multi trench MOSFET of FIG. 2B, in which there is a second conductive type heavily doped region 202 under the barrier layer B1, which can further reduce the electric field there.

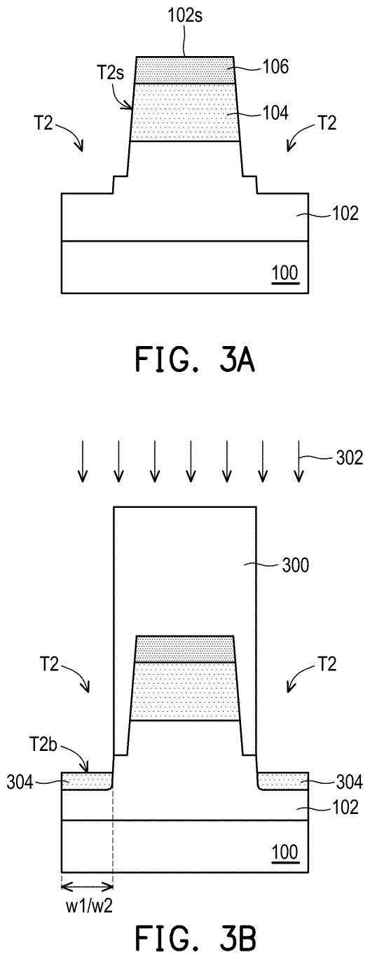

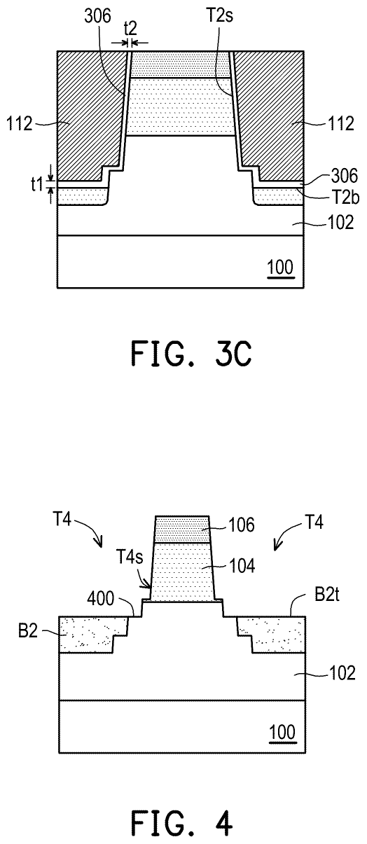

FIG. 3A to FIG. 3C are cross-sectional schematic diagrams of the manufacturing process of a self-align multi trench MOSFET according to the third embodiment of the disclosure. The manufacturing method starts after the steps relative to FIG. 1G, in which the barrier layer is omitted and a forming step of a second conductive type heavily doped region is added. In FIG. 3A to FIG. 3C, the same reference numerals as those in the first embodiment are used to represent the same or similar parts and components. The relevant content of the same or similar parts and components may be referenced from the contents of the first embodiment, and are not repeated herein.

Referring to FIG. 3A, after forming the trench T2 with the stepped sidewalls T2s and removing the patterned hard mask PM′ (of FIG. 1F), there is no filler in the trench T2. In some embodiments, if the processes of FIG. 1F and FIG. 1G are repeated multiple times, a trench with stepped sidewalls T2s having more steps can be formed.

Then, referring to FIG. 3B, a second conductive type ion implantation 302 is performed by using a photomask process to form a second conductive type heavily doped region 304 in the epitaxial layer 102 below the bottom T2b of the trench T2. The above-mentioned photomask process, for example, forms a patterned mask layer 300 (e.g., a photoresist layer) on the regions where the formation of a second conductive type heavily doped region 304 is not desired. Furthermore, the width w2 of the second conductive type heavily doped region 304 can be made equal to the width w1 of the bottom T2b of the trench T2 by controlling the size of the patterned mask layer 300. Alternatively, in other embodiments, the width of the second conductive type heavily doped region 304 is made greater than or less than the width of the bottom T2b of the trench T2.

Afterwards, the process of FIG. 1H to FIG. 1I can be followed to obtain the self-align multi trench MOSFET as shown in FIG. 3C. If the dopant used to form the second conductive type heavily doped region 304 is conducive to increasing the oxidation rate, the thickness t1 of the gate dielectric layer 306 formed on the bottom T2b is greater than the thickness t2 of the gate dielectric layer 306 formed on the stepped sidewall T2s. In another embodiment, the thickness of the gate dielectric layer 306 formed on the bottom T2b may also be equal to the thickness of the gate dielectric layer 306 formed on the stepped sidewall T2s. The greater thickness t1 can substantially reduce the excessive electric field at the bottom of the gate dielectric layer 306 in the trench device structure, thereby improving the device reliability.

FIG. 4 is a cross-sectional schematic diagram of an intermediate stage of the manufacturing process of a self-align multi trench MOSFET according to the fourth embodiment of the disclosure. The manufacturing method is a step that repeats the process depicted in FIG. 1F to FIG. 1G three times, relative to the step illustrated in FIG. 1G.

FIG. 4 shows that a trench T4 with stepped sidewalls is formed in the epitaxial layer 102, and there is a barrier layer B2 in the trench T4. The method of forming the barrier layer B2 may be referenced from the first embodiment, and the top surface B2t of the barrier layer B2 is coplanar with the top 400 of the penultimate step of the stepped sidewall T4s. In this embodiment, the barrier layer B2 at the bottom of the trench T4 can also increase the protection under the gate subsequently formed in the trench T4 and improve the reliability, thereby achieving the effect of optimizing the device.

Subsequently, the step illustrated in FIG. 1H may be performed. In addition, although the fourth embodiment does not involve the formation of a second conductive type heavily doped region, it should be understood that the steps for forming the second conductive type heavily doped region in the aforementioned second embodiment or third embodiment may also be applied to this embodiment.

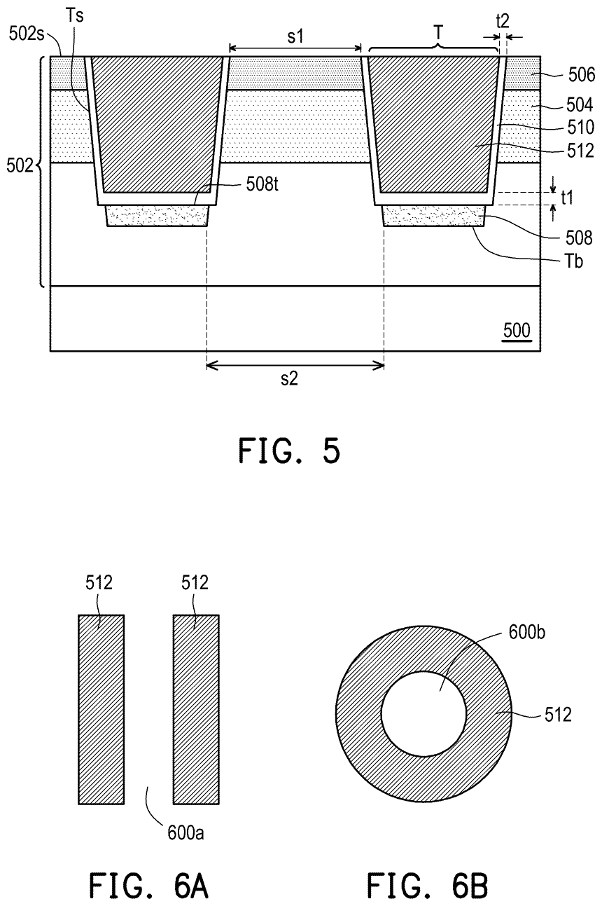

FIG. 5 is a cross-sectional schematic diagram of a self-align multi trench MOSFET according to the fifth embodiment of the disclosure.

Referring to FIG. 5, the self-align multi trench MOSFET of the fifth embodiment includes a substrate 500, an epitaxial layer 502, a deep well region 504, a first conductive type heavily doped region 506, multiple trenches T, a barrier layer 508, a gate dielectric layer 510, and a gate 512. The epitaxial layer 502 is disposed on the substrate 500, and the epitaxial layer 502 has a first conductive type. A deep well region 504 is formed in the epitaxial layer 502, and the deep well region 504 has a second conductive type. In one embodiment, the first conductive type is N type and the second conductive type is P type; in another embodiment, the first conductive type is P type and the second conductive type is N type. The first conductive type heavily doped region 506 is formed in the deep well region 504 of the surface 502s of the epitaxial layer 502. The trench T extends from the surface 502s of the epitaxial layer 502 toward the substrate 500, and the trench T has stepped sidewalls Ts. The spacing s1 at the top of the trench T in the figure is smaller than the spacing s2 at the bottom Tb of the trench T, but not limited thereto. In other embodiments, the spacing s1 at the top of the trench T may also be greater than or equal to the spacing at the bottom Tb of the trench T. In some embodiments, a second conductive type heavily doped region may be formed under the bottom Tb of the trench T (e.g., the second conductive type heavily doped region 202 in FIG. 2B).

Please continue to refer to FIG. 5, the barrier layer 508 in this embodiment is located at the bottom Tb of the trench T, which also has the effect of increasing the protection under the gate 512 and improving reliability. The material of the barrier layer 508 is, for example, but not limited to SiO₂, SiN, or a high-k material. The top surface 508t of the barrier layer 508 may be coplanar with the top of the lowest step of the stepped sidewall Ts, but not limited thereto. In other embodiments, if the stepped sidewall Ts has more than three steps, the top surface of the barrier layer 508 may be coplanar with the top of the penultimate step of the stepped sidewall, and so on. The gate dielectric layer 510 is disposed on the stepped sidewall Ts of the trench T and the barrier layer 508. The material of the gate dielectric layer 510 is, for example, SiO₂, SiN, or a high-k material. In one embodiment, the thickness t1 of the bottom of the gate dielectric layer 510 may be greater than or equal to the thickness t2 of the gate dielectric layer 510 on the stepped sidewall Ts. The gate 512 is disposed in the trench T.

FIG. 6A is a top view of an example of the self-align multi trench MOSFET of FIG. 5. For the sake of clarity, most components are simplified and only the position of the gate 512 is shown. In FIG. 6A, if the trench T in FIG. 5 is a discontinuous trench, the gate is in the form of multiple gates 512. Therefore, the conduction channel 600a is controlled by the gates 512 on both sides.

FIG. 6B is a top view of another example of the self-align multi trench MOSFET of FIG. 5. For the sake of clarity, most components are simplified and only the position of the gate 512 is shown. In FIG. 6B, if the trench T in FIG. 5 is a continuous trench, the gate 512 is in the form of a single gate. Therefore, the conduction channel 600b is controlled by the gate 512 of a single continuous surrounding channel.

To sum up, the method of the disclosure enables the fabrication of a trench gate with stepped sidewalls without requiring an additional photomask process, so there is no additional cost of the photomask process. Moreover, the self-align multi trench MOSFET of the disclosure has a multi trench structure. This approach not only increases the thickness of the gate dielectric layer or barrier layer at the bottom of the gate to reduce the electric field, but also provides greater conduction current and further reduces on-resistance by reducing the trench spacing from both sides through a self-alignment process.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A manufacturing method of a self-align multi trench MOSFET, comprising:
forming an epitaxial layer on a substrate, the epitaxial layer having a first conductive type;
forming a deep well region in the epitaxial layer, the deep well region having a second conductive type;
forming a first conductive type heavily doped region in the deep well region of a surface of the epitaxial layer;
forming a patterned hard mask on the surface of the epitaxial layer to expose a portion of the epitaxial layer;
performing a multiple trench formation process to form a plurality of trenches with stepped sidewalls in the epitaxial layer, each process within the multiple trench formation process comprising:
etching the exposed epitaxial layer; and
trimming the patterned hard mask to expose the surface of the epitaxial layer;
removing the patterned hard mask;
forming a gate dielectric layer above a bottom and the stepped sidewall of the trenches; and
forming a gate in the trenches.

2. The manufacturing method of the self-align multi trench MOSFET according to claim 1, wherein a thickness of the gate dielectric layer formed on the bottom of the trenches is greater than or equal to a thickness of the gate dielectric layer formed on the stepped sidewall.

3. The manufacturing method of the self-align multi trench MOSFET according to claim 1, further comprising forming a second conductive type heavily doped region below the bottom of an initial trench formed in the etched epitaxial layer during a first process of the multiple trench formation process.

4. The manufacturing method of the self-align multi trench MOSFET according to claim 1, further comprising performing a second conductive type ion implantation by using a photomask process after performing the multiple trench formation process to form a second conductive type heavily doped region under the bottom of the trenches.

5. The manufacturing method of the self-align multi trench MOSFET according to claim 1, further comprising forming a barrier layer at the bottom of the trenches before forming the gate dielectric layer, wherein a material of the barrier layer comprises SiO₂, SiN, or a high-k material.

6. A manufacturing method of a self-align multi trench MOSFET, comprising:
forming an epitaxial layer on a substrate, the epitaxial layer having a first conductive type;
forming a deep well region in the epitaxial layer, the deep well region having a second conductive type;
forming a first conductive type heavily doped region in the deep well region of a surface of the epitaxial layer;
forming a patterned hard mask on the surface of the epitaxial layer to expose a portion of the epitaxial layer;
performing a first etching to the exposed epitaxial layer to form a plurality of trenches;
forming a material layer in the trenches, the material layer having etching selectivity relative to the epitaxial layer;
trimming the patterned hard mask to expose a portion of the surface of the epitaxial layer;
performing a second etching on the exposed epitaxial layer to expand the trenches and form a stepped sidewall therein;
removing the patterned hard mask;
removing the material layer;
forming a gate dielectric layer above a bottom and the stepped sidewall of the trenches; and
forming a gate in the trenches.

7. The manufacturing method of the self-align multi trench MOSFET according to claim 6, further comprising repeating the following steps at least once after expanding the trenches:
trimming the patterned hard mask; and
performing the second etching.

8. The manufacturing method of the self-align multi trench MOSFET according to claim 6, further comprising forming a barrier layer at the bottom of the trenches before forming the gate dielectric layer, wherein a material of the barrier layer comprises SiO₂, SiN, or a high-k material.

9. The manufacturing method of the self-align multi trench MOSFET according to claim 8, wherein forming the barrier layer comprises first performing a deposition process followed by an etch-back process.

10. The manufacturing method of the self-align multi trench MOSFET according to claim 8, wherein forming the barrier layer comprises first performing an ion implantation process followed by an oxidation process.

11. The manufacturing method of the self-align multi trench MOSFET according to claim 6, further comprising forming a second conductive type heavily doped region under the bottom of the trenches before forming the material layer.

12. The manufacturing method of the self-align multi trench MOSFET according to claim 6, further comprising performing a second conductive type ion implantation by using a photomask process after removing the patterned hard mask to form a second conductive type heavily doped region under the bottom of the trenches.

13. A self-align multi trench MOSFET, comprising:
a substrate;
an epitaxial layer, disposed on the substrate, the epitaxial layer having a first conductive type;
a deep well region, formed in the epitaxial layer, the deep well region having a second conductive type;
a first conductive type heavily doped region, formed in the deep well region of a surface of the epitaxial layer;
a plurality of trenches, extending from the surface of the epitaxial layer toward the substrate, and the trenches having a stepped sidewall;
a barrier layer, located at a bottom of the trenches;
a gate dielectric layer, disposed on the stepped sidewall of the trenches and the barrier layer; and
a gate, disposed in the trenches.

14. The self-align multi trench MOSFET according to claim 13, wherein the trenches are discontinuous trenches, and the gate is in a form of a plurality of gates.

15. The self-align multi trench MOSFET according to claim 13, wherein the trenches are continuous trenches, and the gate is in a form of a single gate.

16. The self-align multi trench MOSFET according to claim 13, further comprising a second conductive type heavily doped region formed under the bottom of the trenches.

17. The self-align multi trench MOSFET according to claim 13, wherein a material of the barrier layer comprises SiO₂, SiN, or a high-k material.

18. The self-align multi trench MOSFET according to claim 13, wherein a top surface of the barrier layer is coplanar with a top of a lowest step of the stepped sidewall.

19. The self-align multi trench MOSFET according to claim 13, wherein a top surface of the barrier layer is coplanar with a top of a penultimate step of the stepped sidewall.

20. The self-align multi trench MOSFET according to claim 13, wherein a thickness of a bottom of the gate dielectric layer is greater than or equal to a thickness of the gate dielectric layer on the stepped sidewall.
